(19) United States
(12) Patent Application Publication
(10) Pub. No.: US 2025/0233111 A1
(43) Pub. Date: Jul. 17, 2025

(54) SEMICONDUCTOR PACKAGE AND MANUFACTURING METHOD OF THE SAME

(71) Applicant: Taiwan Semiconductor Manufacturing Company, Ltd., Hsinchu (TW)

(72) Inventors: Cheng-Shiuan Wong, Hsinchu City (TW); Chia-Shen Cheng, Hsinchu County (TW); Hsin Liang Chen, New Taipei City (TW); Wei-Yu Chen, New Taipei City (TW); Hao-Jan Pei, Hsinchu (TW); Hsiu-Jen Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 18/415,529

(22) Filed: Jan. 17, 2024

(51) Int. Cl. H01L 25/065; H01L 21/56; H01L 23/00; H01L 23/31; H01L 23/522; H01L 23/538

(52) U.S. Cl. CPC H01L 25/0655; H01L 21/563; H01L 23/31; H01L 23/5226; H01L 23/5383; H01L 24/16; H01L 24/32; H01L 24/73; H01L 24/92; H01L 2224/16145; H01L 2224/32145; H01L 2224/73204; H01L 2224/92125

(57) ABSTRACT

A package structure and manufacturing methods thereof are described. The package structure includes an interposer substrate, a first semiconductor die, a second semiconductor die, an underfill, and an insulating encapsulant. The first and second semiconductor dies are disposed on the interposer substrate. The underfill is disposed between the first semiconductor die and the interposer substrate. The insulating encapsulant is disposed on the interposer substrate. The insulating encapsulant includes a first portion and a second portion. The first portion laterally encapsulates the first semiconductor die and the second semiconductor die. The second portion is disposed between the second semiconductor die and the interposer substrate.

### BACKGROUND

The electronics industry has experienced an increasing demand for smaller and faster electronic devices that are simultaneously able to support a greater number of increasingly complex and sophisticated functions. In order to meet these demands, there is a continuing trend in the integrated circuit (IC) industry to improve the integration density of various semiconductor devices and/or electronic components. This can be achieved by reducing IC dimensions (for example, by reducing minimum IC feature size), thereby allowing different types of components of various functions to be integrated into a given area. However, such scaling has also increased complexity of IC manufacturing processes. Thus, there is a need for more advanced packaging techniques for semiconductor dies, to realize the continued advances in IC devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 5, FIG. 7, and FIG. 9 through FIG. 10 are schematic cross-sectional views illustrating structures produced at various stages of a manufacturing method of a semiconductor package, according to some embodiments of the present disclosure.

FIG. 6A and FIG. 6B are schematic cross-sectional views illustrating a process flow for fabricating—an insulating encapsulant according to some other embodiments of the present disclosure.

FIG. 8A and FIG. 8B are schematic cross-sectional views illustrating a process flow for fabricating an insulating encapsulant according to some alternative embodiments of the present disclosure.

FIG. 11 is a schematic cross-sectional view illustrating a semiconductor package connected to a package substrate according to some embodiments of the present disclosure.

FIG. 12 is a schematically enlarged, cross-sectional view showing a plurality of openings on an insulating encapsulant disposed at a second region of an interposer substrate of FIG. 7, according to various aspects of the present disclosure.

### DETAILED DESCRIPTION

The present disclosure relates generally to packaging devices and methods of manufacturing, for semiconductor devices.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

To reduce warpage and prevent solder joints and/or bridging of solder joints in a semiconductor package, various novel package structures, and methods of manufacturing thereof are provided according to various embodiments. Throughout the various views and illustrative embodiments, like reference numbers are used to designate like elements.

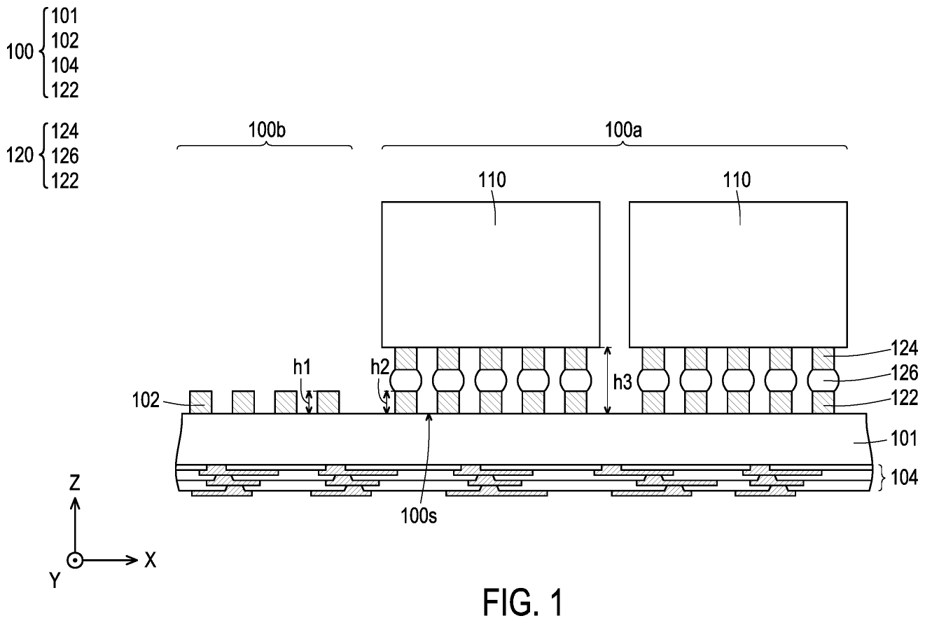

FIG. 1 through FIG. 5, FIG. 7, and FIG. 9 through FIG. 10 are schematic cross-sectional views illustrating structures produced at various stages of a manufacturing method of a semiconductor package, according to some embodiments of the present disclosure.

Referring to FIG. 1, an interposer substrate 100 is provided. The interposer substrate 100 includes a first region 100a and a second region 100b. At least one first semiconductor die 110 is provided and disposed on the first region 100a of the interposer substrate 100. The first semiconductor die 110 is electrically connected to the interposer substrate 100 through first conductive terminals 120. The first conductive terminals 120 include first conductive bumps 122 in contact with top surface 100s of the interposer substrate 100, second conductive bumps 124 in contact with bottom surface of the first semiconductor die 110, and solder regions 126 between the first conductive bumps 122 and the second conductive bumps 124. The interposer substrate 100 further includes first conductive pillars 102 disposed at the second region 100b of the interposer substrate 100. In some embodiments, the interposer substate 100 include an organic interposer substrate or an inorganic interposer substrate. For example, the above-mentioned inorganic interposer substate 100 may be or include a semiconductor interposer substate (e.g., a silicon interposer substate 100) or other suitable interposer substate. Take the semiconductor interposer substate as an example, the interposer substate 100 may include a semiconductor substrate 101, such as silicon substrate in wafer form, wherein the first conductive pillars 102 and first conductive bumps 122 are distributed on the top surface (i.e., the top surface 100s of the interposer substrate 100) of the silicon substrate 101. In some embodiments, the interposer substate 100 further includes through semiconductor vias (e.g., through silicon vias) penetrating through the semiconductor substrate 101. In some embodiments, the interposer substate 100 is an active interposer substrate having active devices (e.g., transistors) and passive devices (e.g., resistors, capacitors, an/or inductors) integrated therein. In some embodiments, the interposer substate 100 is an interposer substrate having through vias, and no active device (e.g., transistor) and passive device (e.g., resistor, capacitor, an/or inductor) is formed therein.

In some embodiments, the first conductive bumps 122, the second conductive bumps 124 and the first conductive pillars 102, includes copper, copper alloys, or other conductive materials, and may be formed by deposition (e.g., plating) or other suitable techniques. In some embodiments, the solder regions 126 include eutectic solder or non-eutectic solder, and may for example, be lead or be lead-free, and may include Sn—Ag, Sn—Cu, Sn—Ag—Cu, or the like. In some embodiments, the formation of the first conductive bumps 122, second conductive bumps 124 and the first conductive pillars 102 includes a deposition process of a seed layer, formation of a photoresist layer on the seed layer, a patterning process (e.g., a photolithography process) to form openings in the photoresist layer, a deposition process for forming conductive material in the openings of the patterned photoresist layer, a removal process of the patterned photoresist layer (e.g., a photoresist stripping process), and a removal process (e.g., an etch process) for removing portions of the seed layer which are not covered by the conductive material. In some embodiments, the first conductive bumps 122 and the first conductive pillars 102 are formed with substantially equal height. A height h1 of the first conductive pillars 102 is the same as a height h2 of the first conductive bumps 122, the height h1 and the height h2 may be in the range from about 10 μm to about 70 μm. In some embodiments, the first conductive pillars 102 and the first conductive terminals 120 may be formed with different heights. A height h3 of the first conductive terminals 120 is higher than the height h1 of the first conductive pillars 102 and the height h2 of the first conductive bumps 122. However, the disclosure is not limited by the height h1 of the first conductive pillars 102, the height h2 of the first conductive bumps 122 and the height h3 of the first conductive terminals 120, as the heights of h1, h2, and h3 may be adjusted according to the design or production requirements.

In some embodiments, the interposer substate 100 further includes a redistribution structure 104, wherein the redistribution structure 104 is electrically connected to the first conductive bumps 122 and the first conductive pillars 102 through the through semiconductor vias (not shown) embedded in the semiconductor substrate 101. As illustrate in FIG. 1, the redistribution structure 104 is distributed on the bottom surface which is opposite to the top surface 100s of the interposer substrate 100. In some embodiments, the interposer substrate 100 including the first conductive bumps 122, the first conductive pillars 102 and the redistribution structure 104 is provided. Then, the first semiconductor dies 110 including the second conductive bumps 124 and the solder regions 126 are provided over the interposer substrate 100. Through proper alignment, the solder regions 126 may align with and be in contact with the first conductive bumps 122. Then, a reflow process may be performed such that the first conductive bumps 122 are bonded with the second conductive bumps 124 through the molten solder regions 126.

As illustrated in FIG. 1, two first semiconductor dies 110 are shown to represent plural dies, but the number of dies in the semiconductor package is not limited by the embodiments. Each one of the first semiconductor dies 110 may respectively be or include a logic die, such as a central processing unit (CPU) die, a graphic processing unit (GPU) die, a micro control unit (MCU) die, an input-output (I/O) die, a baseband (BB) die, or an application processor (AP) die. In some embodiments, at least one of the first semiconductor dies 110 include a memory die such as such as a high-bandwidth-memory (HBM) die. In some embodiments, the first semiconductor dies 110 may be the same type of dies or perform the same functions. In some embodiments, the first semiconductor dies 110 may be different types of dies or perform different functions. In some embodiments, the first semiconductor dies 110 includes a logic die and a memory die.

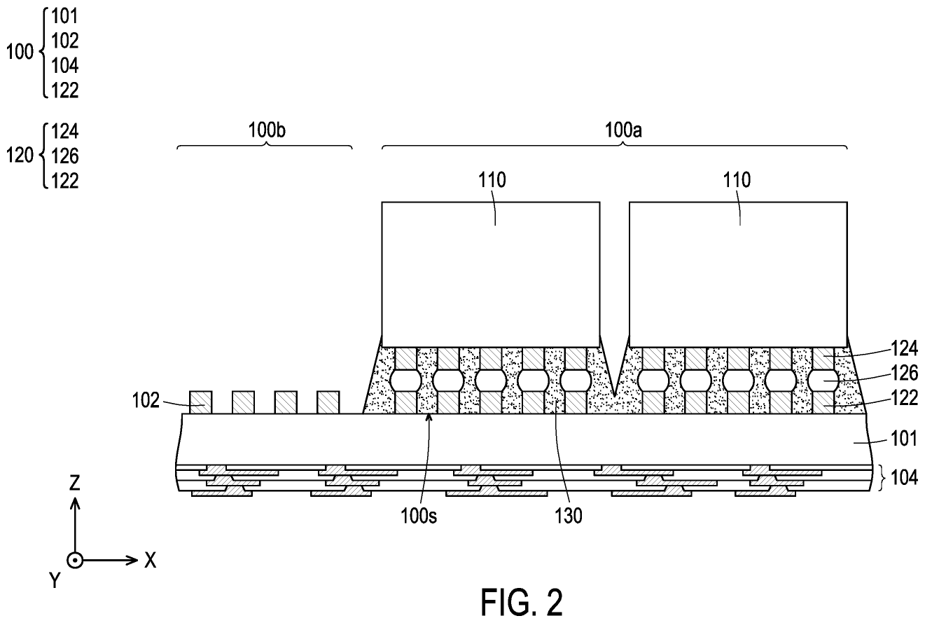

Referring to FIG. 2, after the first semiconductor dies 110 are provided over and electrically connected to the first region 100a of the interposer substrate 100 via the first conductive terminals 120, an underfill 130 may be formed between the first semiconductor dies 110 and the first region 100a of the interposer substrate 100, and laterally encapsulates the first conductive terminals 120. The underfill 130 at least fills gaps between the first semiconductor dies 110 and the first region 100a of the interposer substrate 100, and may also wraps sidewalls of the first conductive terminals 120. The material of the underfill 130 includes molding compound, resin, polymer, oxide materials, nitride materials or combination thereof. In some embodiments, the underfill 130 may be or include epoxy resin. The underfill 130 may be formed by underfill dispensing, a capillary flow process, or any other suitable method. In some embodiments, the underfill 130 is dispensed into the gaps between the first semiconductor dies 110 and the first region 100a of the interposer substrate 100, using for example, a dispensing needle or other suitable dispensing tools, and then cured to harden. The underfill 130 enhances the bonding strength between the first semiconductor dies 110 and the interposer substrate 100.

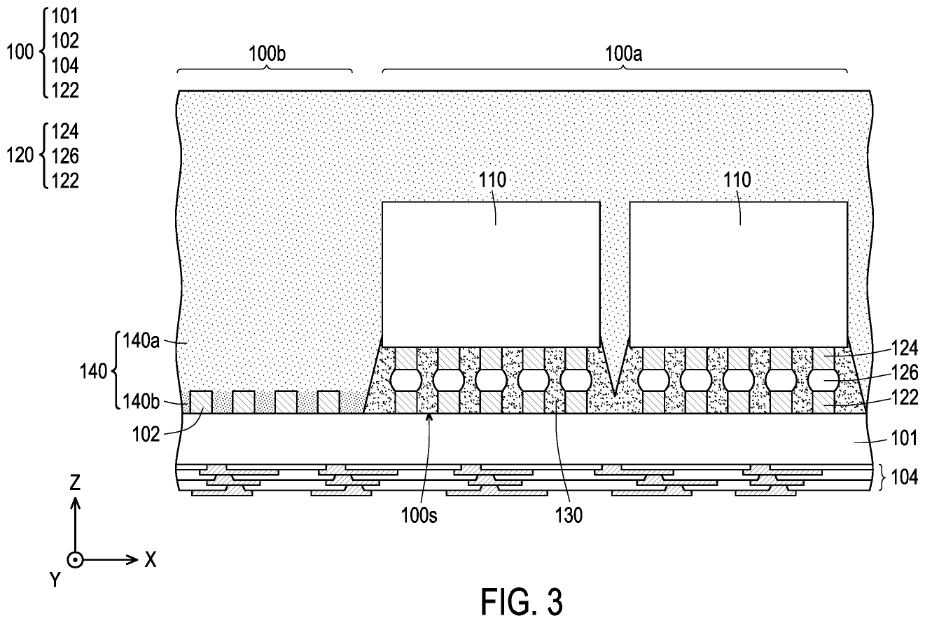

Referring to FIG. 3, after forming the underfill 130, an insulating encapsulant 140 is formed on the interposer substrate 100 as illustrated in FIG. 2. The insulating encapsulant 140 includes a first portion 140a and a second portion 140b. The first portion 140a of the insulating encapsulant 140 covers the second portion 140b of the insulating encapsulant 140 and the first conductive pillars 102. The first portion 140a of the insulating encapsulant 140 is in contact with the top surfaces of the first conductive pillars 102, and the second portion 140b of the insulating encapsulant 140 is in contact with sidewalls of the first conductive pillars 102. The first portion 140a laterally encapsulates the first semiconductor dies 110. The second portion 140b of the insulating encapsulant 140 is disposed between the first portion 140a and the top surface 100s of the interposer substrate 100, and laterally encapsulates the first conductive pillars 102. The insulating encapsulant 140 at least fills up gaps between the first semiconductor dies 110, between the underfill 130 underlying the first semiconductor dies 110, and between the underfill 130 and the first conductive pillars 102, and may also surrounds and covers the first conductive pillars 102. In some embodiments, the insulating encapsulant 140 may be formed by a molding process, for example, transfer molding, compression molding, liquid encapsulant molding process, and the like. In some embodiments, the insulating encapsulant 140 include for example, epoxy resins, phenolic resins, silicon-containing resins, dielectric materials, or other suitable materials.

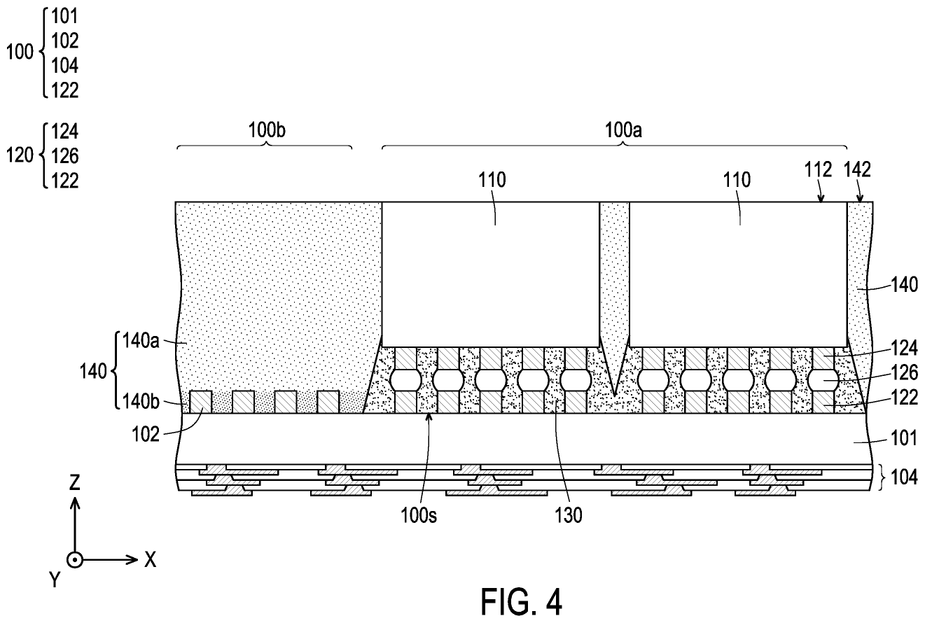

Referring to FIG. 4, after the insulating encapsulant 140 is formed on the interposer substrate 100 as illustrated in FIG. 3, the insulating encapsulant 140 is partially removed or planarized by, for example, mechanical grinding, chemical-mechanical polishing (CMP), etching or combinations thereof. The planarization may further result in a top surface 112 of the first semiconductor dies 110 being substantially flush with a top surface 142 of the insulating encapsulant 140. As illustrated in FIG. 4, the top surface 142 of the insulating encapsulant 140 substantially levels with the top surface 112 of the first semiconductor dies 110.

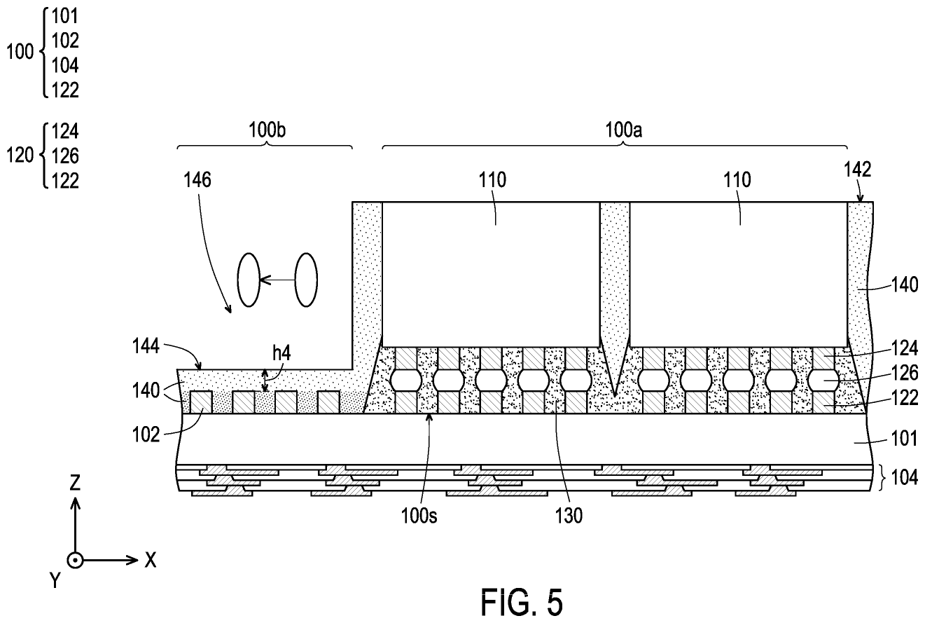

Referring to FIG. 5, in some embodiments, a portion of the insulating encapsulant 140 at the second region 100b of the interposer substrate 100 as illustrated in FIG. 4, is partially removed or trimmed to form a remaining portion 146 of the insulating encapsulant 140, The remaining portion 146 of the insulating encapsulant 140 covers the second region 100b of the interposer substrate 100. The insulating encapsulant 140 is partially removed or trimmed from the top surface 142 of the insulating encapsulant 140 over the second region 100b of the interposer substrate 100 using for example, a contact cutting process. In some embodiments, the contact cutting process is performed by a mechanical cutting process, such as blade sawing. The removal or trimming process removes the insulating encapsulant 140 to create a new surface 144, which is lower than the top surface 142 of the insulating encapsulant 140 over the first region 100a of the interposer substrate 100. In some embodiments, a thickness h4 of the insulating encapsulant 140 remains at the second region 100b of the interposer substrate 100.

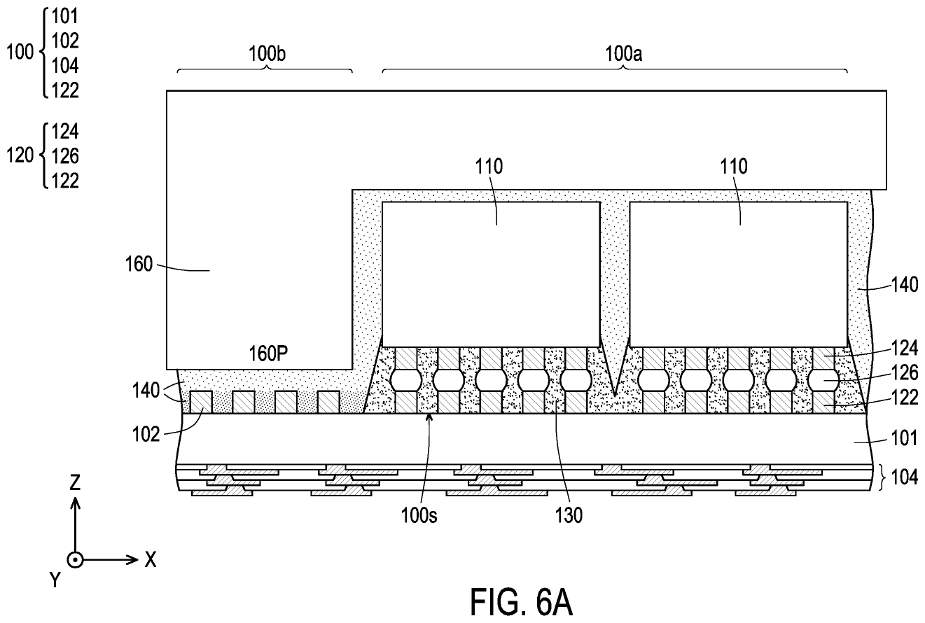

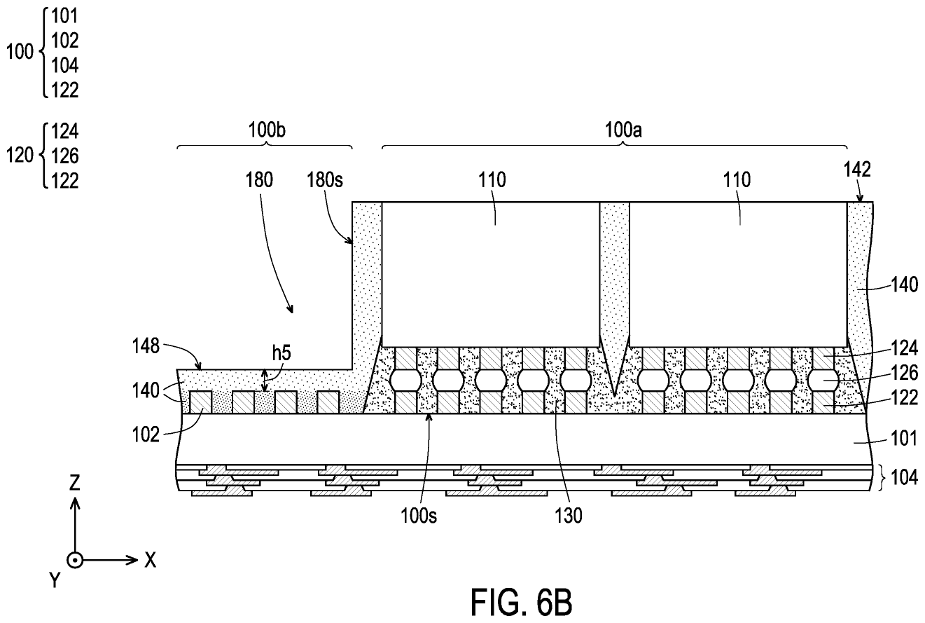

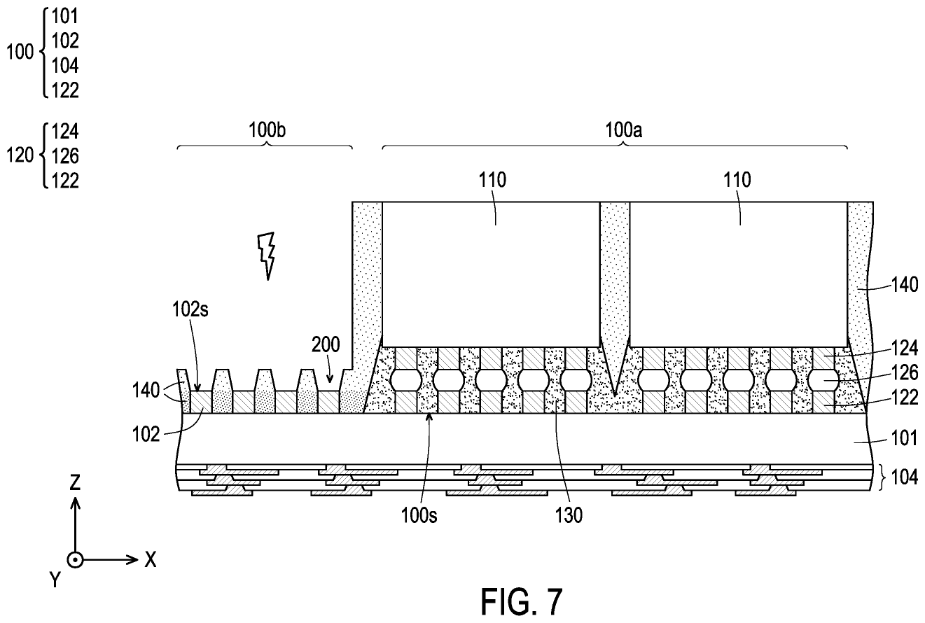

Referring to FIGS. 6A and 6B, in an alternative embodiment, the insulating encapsulant 140 may be formed on the interposer substrate 100 by an over-molding process followed by a planarization process. In some embodiment, the interposer substrate 100 includes a first region 100a and a second region 100b. The interposer substrate 100 includes the first conductive bumps 122, the first conductive pillars 102 and the redistribution structure 104. The molding process may be performed in a molding device (not shown), which comprises a mold chase 160. As illustrated in FIG. 6A, the mold chase 160 is disposed over the interposer substrate 100,—first semiconductor die(s) 110 disposed on the first region 100a of the interposer substrate 100 and first conductive pillars 102 disposed on the second region 100b of the interposer substrate 100. The mold chase 160 disposed over a top surface 100s of the interposer substrate 100 may be in a predetermined shape or configuration for retaining the insulating encapsulant 140 when applied. In some embodiments, the mold chase 160 disposed over the top surface 100s of the interposer substrate 100 may have different heights. In some embodiments, the mold chase 160 includes a protrusion 160P protruding from the mold chase 160 towards the second region 100b of the interposer substrate 100. In some embodiments, the protrusion 160P is disposed over the first conductive pillars 102, or adjacent to the first semiconductor die(s) 110. In some embodiments, the mold chase 160 includes steel or the like.

As illustrated in FIG. 6A, the insulating encapsulant 140 is disposed between the mold chase 160 and the interposer substrate 100. In some embodiments, a space defined by the mold chase 160, the first semiconductor die(s) 110 and the first conductive pillars 102 is filled by the insulating encapsulant 140. In some embodiments, the insulating encapsulant 140 includes molding compound, molding underfill, epoxy, resin, or the like. In some embodiments, a curing process may be performed to solidify the insulating encapsulant 140. In some embodiments, the mold chase 160 is removed after forming the insulating encapsulant 140. In some embodiments, the first conductive pillars 102 formed on the second region 100b of the interposer substate 100 are surrounded by the insulating encapsulant 140. In some embodiments, the first semiconductor die(s) 110 formed on the first region 100a of the interposer substrate 100 is laterally encapsulated by the insulating encapsulant 140.

As illustrated in FIG. 6B, in some embodiments, the molding process includes a recess 180 formed over the second region 100b of the interposer substrate 100. In some embodiments, a top surface 148 of the insulating encapsulating 140 at the second region 100b of the interposer substrate 100 is non-coplanar with a top surface 142 of the insulating encapsulant 140 at the first region 100a of the interposer substrate 100. In some embodiments, a sidewall 180s of the recess 180 is conformal to an outer surface of the protrusion 160P of the mold chase 160 illustrated in FIG. 6A. In some embodiment, the recess 180 is adjacent to the first semiconductor die(s) 110. In some embodiments, a thickness h5 of the insulating encapsulant 140 is formed over the first conductive pillars 102 of the second region 100b of the interposer substrate 100. In some embodiments, the thickness h4 (FIG. 5) and thickness h5 (FIG. 6B) of the insulating encapsulant 140 may be independently of each other, in the range between 10 μm to 30 μm, but the disclosure is not limited thereto. The thickness h4 (FIG. 5), and thickness h5 (FIG. 6B) may be adjusted according to design or performance requirements. The encapsulated interposer substrate 100 and the insulating encapsulant 140 may be subjected to additional post-molding process or patterning process in subsequent process step(s). Although just one package is shown being formed, it should be understood that an array of packages including multiple interposer substrates 100 may be manufactured simultaneously in a strip or array configuration, which are separated or singulated in subsequent step(s).

Referring to FIG. 7, in some embodiments, the insulating encapsulant 140 at the second region 100b of the interposer substrate 100 formed according to processes as illustrated in FIG. 5 and FIG. 6B, may be further patterned to form a plurality of openings 200 on a top surface 144, 148 of the insulating encapsulant 140 at the second region 100b of the interposer substrate 100, thereby revealing top surfaces 102s of the underlying first conductive pillars 102. The insulating encapsulant 140 may be patterned by, for example, etching, milling, laser techniques, a combination thereof. In some embodiments, the insulating encapsulant 140 may be patterned using, e.g., a laser drilling process. For example, a laser is directed towards those portions of the insulating encapsulant 140 which are to be removed in order to reveal the underlying top surfaces 102s of the first conductive pillars 102. During the laser drilling process, the drill energy may be in a range from 0.1 mJ/mm² to about 1.0 mJ/mm², and the drill angle may be about 0 degree (perpendicular to the top surface 144, 148 of the insulating encapsulant 140) to normal of the top surface 144, 148 of the insulating encapsulant 140. The patterning may be performed to form a plurality of openings 200 on the insulating encapsulant 140. The openings 200 may penetrate through the insulating encapsulant 140 in direction Z, towards the top surface 100s of the interposer substrate 100.

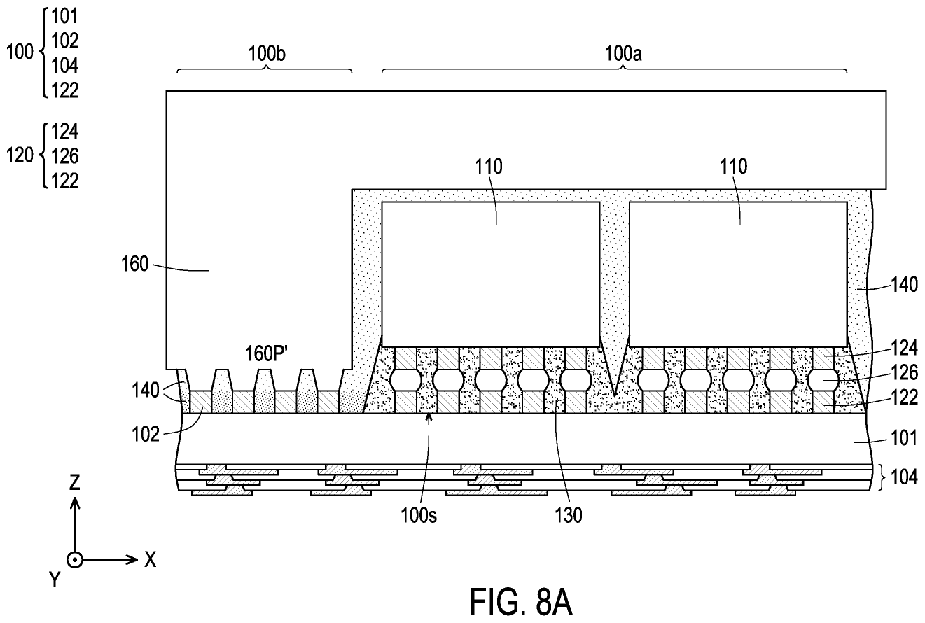

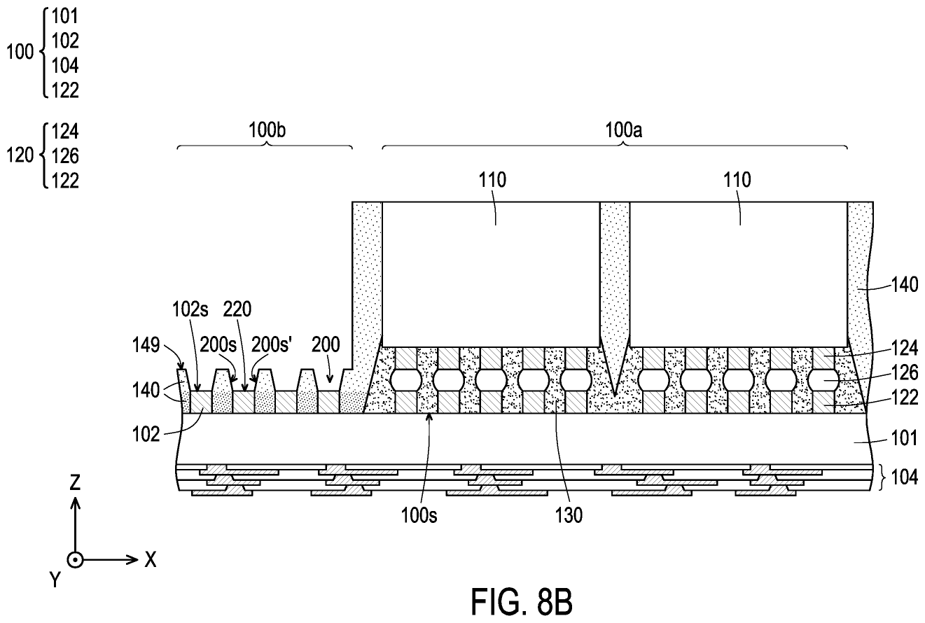

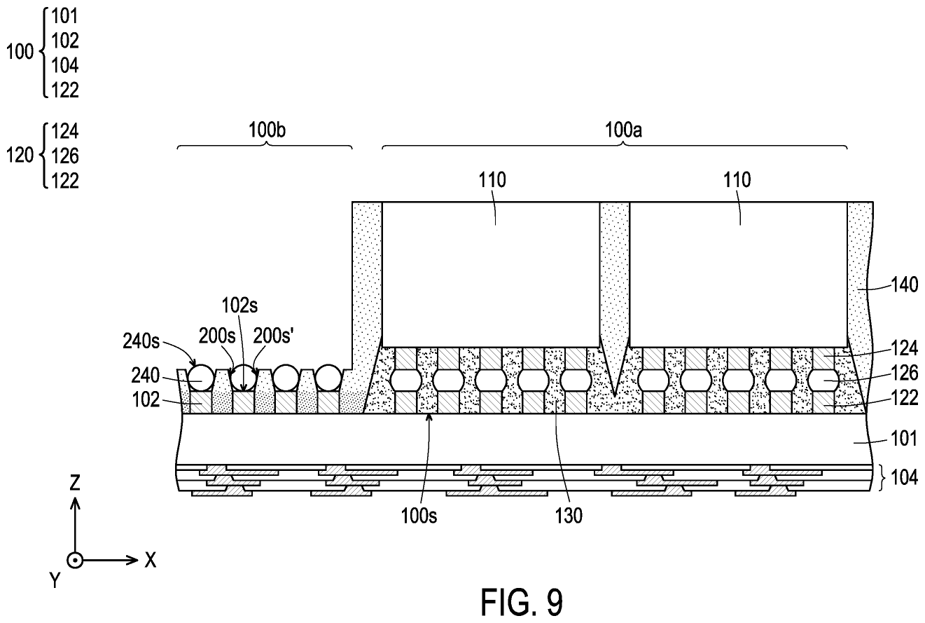

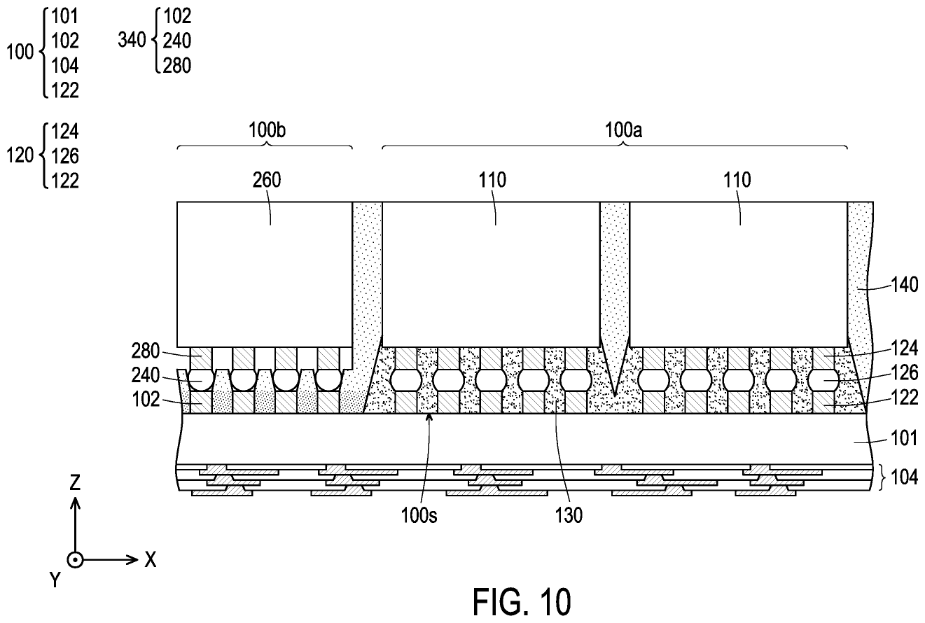

Referring to FIGS. 8A and 8B, in an alternative embodiment, the insulating encapsulant 140 may be formed on the interposer substrate 100 by a molding process. The molding process is similar as described above or illustrated in FIGS. 6A and 6B. The mold chase 160 may be sized and shaped such that a space defined by the mold chase 160 allows the insulating encapsulant 140, when filled, to be formed in a shape in accordance with the present embodiment. In some embodiment, the mold chase 160 includes a plurality of protrusions 160P′ protruding from the mold chase 160 towards the second region 100b of the interposer substrate 100. The shape of the mold chase 160 and number of protrusions 160P′ are not limited in the disclosure, and may be designated and selected based on the demand and design layout. In some embodiments, each of the protrusions 160P′ has a tapered profile, and the molding process results in a plurality of openings 200 formed on the top surface 149 of the insulating encapsulant 140, revealing the top surfaces 102s of the first conductive pillars 102. In some embodiments, forming the openings 200 on the top surface 100s of the interposer substrate 100 through a mold patterning process, eliminates the need for additional patterning steps, for example, laser drilling. In some embodiments, a height of the protrusions 160P′ of the mold chase 160 is substantially equals to a depth of the openings 200. As illustrated in FIG. 8B, sidewalls 200s, 200s′ of the openings 200 of the insulating encapsulant 140 are conformal to an outer surface of the protrusions 160P′ of the mold chase 160. In some embodiments, each of the openings 200 has two tapered side walls 200s, 200s′ and a horizontal bottom pit surface 220 connecting the sidewalls 200s, 200s′. Each of the openings 200 corresponds to a region where a solder region (not shown) is to be placed (solder region attachment location) in a subsequent step(s) of the process.

Referring to FIG. 9, after the top surfaces 102s of the first conductive pillars 102 are revealed by the insulating encapsulant 140, by steps as illustrated in FIG. 5 through FIGS. 8A and 8B, solder regions 240 are formed on the top surface 102s of the first conductive pillars 102. In some embodiments, the solder regions 240 are disposed within the openings 200 formed on the insulating encapsulant 140, such that the peripheral of the solder regions 240 is in contact with the side walls 200s, 200s′ of the openings 200, and topmost surface 240s of the solder regions 240 are exposed by the openings 200. Through the openings 200 formed on the insulating encapsulant 140, the solder regions 240 formed within the openings 200 can be accessibly revealed by the insulating encapsulant 140, thereby facilitating the placement of semiconductor die(s) in a subsequent step(s).

Referring to FIG. 10, a second semiconductor die 260 is disposed on the second region 100b of the interposer substrate 100. The second semiconductor die 260 is electrically connected to the interposer substrate 100 via second conductive terminals 340 formed between the top surface 100s of the interposer substrate 100 and a bottom surface of the second semiconductor die 260. The second conductive terminals 340 comprise first conductive pillars 102 contacting the top surface 100s of the interposer substrate 100, second conductive pads 280 contacting the bottom surface of the second conductive die 260, and solder regions 240 between the first conductive pillars 102 and the second conductive pads 280. Since the die bonding process of the second semiconductor die 260 is performed after the fabrication of the insulating encapsulant 140, air gaps may generate between the second semiconductor die 260 and the insulating encapsulant 140 which is distributed on the second region 100b of the interposer substrate 100. As illustrated in FIG. 10, the second semiconductor die 260 may be disposed such that no underfill 130 is formed between the second semiconductor die 260 and the portion of the insulating encapsulant 140 which is distributed on the second region 100b of the interposer substrate 100, but the disclosure is not limited thereto. As illustrated in FIG. 10, the second semiconductor die 260 and the insulating encapsulant 140 may be separated by air gaps. In some embodiments, the air gaps are formed between second conductive pads 280 attached to the bottom surface of the second semiconductor die 260. In some other embodiment, the air gaps may be further filled by another underfill. In some embodiments, the underfill 130 is omitted, for example, at the second region 100b of the interposer substrate 100, in which case, the insulating encapsulant 140 occupies all space between the second semiconductor die 260 and the second region 100b of the interposer substrate 100, and laterally encapsulates the first conductive pillars 102 at the second region 100b of the interposer substrate 100. In other words, at the second region 100b of the interposer substrate 100, the second conductive pads 280 may protrude into the openings 200 (illustrated in FIG. 7 or FIG. 8B), and the insulating encapsulant 140 is in contact with the second semiconductor die 260 directly.

As illustrated in FIG. 10, a sidewall of the second semiconductor die 260 is in contact with the insulating encapsulant 140. In some other embodiments, the second semiconductor die 260 is not in contact with the insulating encapsulant 140. In other words, the second semiconductor die 260 may be laterally spaced apart from the insulating encapsulant 140 by an air gap. Furthermore, the air gap laterally separating the second semiconductor die 260 and the insulating encapsulant 140 may be filled by another underfill (not shown in FIG. 10).

A reflow process is then performed to join the first conductive pillars 102 on the top surface 100s of the interposer substrate 100 with the first conductive pads 280 of the second semiconductor die 260. The reflow temperature and the processing time of the reflow process can be optimized depending on the compositions of the first conductive pillars 102, first conductive pads 280, and the solder regions 240. In some embodiments, joint shifting can be reduced and the second semiconductor die 260 is attached to the intended position on the interposer substrate 100 in a precise manner. When better placement is achieved, packages with fine pitch or smaller form factors can be formed.

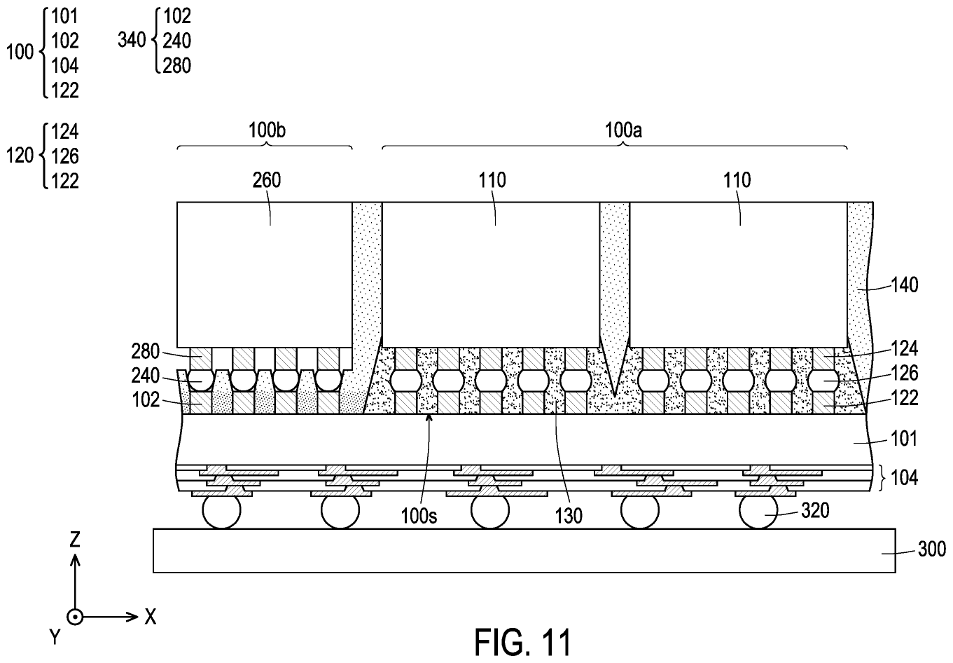

Referring to FIG. 10 and FIG. 11, after performing the die bonding process of the second semiconductor die 260, conductive bumps 320 are formed on the bottom surface of the interposer substrate 100, for example, through a wafer level bumping process. The conductive bumps 320 may be formed on the bottom surface of the redistribution structure 104 of the interposer substrate 100. The conductive bumps 320 may be or include Controlled Collapse Chip Connection bumps (C4 bumps). After forming the conductive bumps 320, a singulation process may be performed to cut the interposer substrate 100 and the resulted structure formed thereon such that singulated semiconductor devices are obtained.

As illustrate in FIG. 10 and FIG. 11, a package substrate 300 is provided, and at least one of the above-mentioned singulated semiconductor devices is disposed over and mounted onto the package substrate 300, such that the conductive bumps 320 are sandwiched between the interposer substrate 100 and the package substrate 300 for electrically connecting the interposer substrate 100 and the package substrate 300. The package substrate 300 may be a printed circuit board or other suitable types of wiring substrate. In addition, on the bottom surface of the package substrate 300, conductive terminals (not shown) may be formed. In some embodiments, the conductive terminals formed on the bottom surface of the package substrate 300 include solder balls (e.g., ball grid array (BGA) balls).

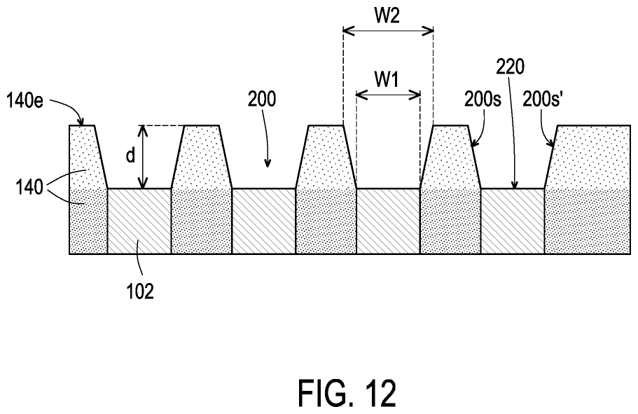

Referring to FIG. 12, an enlarged schematic cross-sectional view of a plurality of openings 200 formed on an insulating encapsulant 140 at a second region 100b of the interposer substrate 100 of FIG. 7 is provided. In some embodiments, the openings 200 may penetrate through the insulating encapsulant 140 in the direction Z, and the openings 200 may be formed to further extend from an edge 140e of the insulating encapsulant 140 in direction X. In some embodiments, each of the openings 200 has two tapered side walls 200s, 200s′, and a horizontal bottom pit surface 220 in between the tapered side walls 200s, 200s′. The vertical depth d of each of the openings, measured in the direction Z may approximately range from about 10 μm to about 30 μm. As illustrated in FIG. 12, the horizontal bottom pit surface 220 on each of the openings 200 is extending from (e.g., not leveled with) the edge surface 140e of the insulating encapsulant 140 towards the top surface 100s of the interposer substrate 100 of FIG. 7. Each of the openings includes a bottom horizontal width w1 and top horizontal width w2, measured in the direction X. The bottom horizontal width w1 may be different from the top horizontal width w2. In some embodiment, the top horizontal width w2 is greater than bottom horizontal width w1, wherein the top horizontal width w2 may approximately range from about 25 μm to about 50 μm, and the bottom horizontal width w1 may approximately range from about 20 μm to about 30 μm. In some embodiment, the top horizontal width w2 is greater than a maximum diameter of the solder regions (not shown), to achieve more optimized placement of the solder regions within the openings of the insulating encapsulant 140.

In accordance with some embodiments of the disclosure, a structure including an interposer substrate, a first semiconductor die, a second semiconductor die, an underfill and an insulating encapsulant is provided. The first and second semiconductor dies are disposed on the interposer substrate. The underfill is disposed between the first semiconductor die and the interposer substrate. The insulating encapsulant comprises a first portion and a second portion, the first portion covers the second portion, the first portion laterally encapsulates the first semiconductor die and the second semiconductor die, and the second portion is disposed between the second semiconductor die and the interposer substrate. In some embodiments, the first semiconductor die is electrically connected to the interposer substrate via first conductive terminals between a top surface of the interposer substrate and a bottom surface of the first semiconductor die, and the second semiconductor die is electrically connected to the interposer substrate via second conductive terminals between the top surface of the interposer substrate and a bottom surface of the second semiconductor die. In some embodiments, the underfill laterally encapsulates the first conductive terminals, and the second portion of the insulating encapsulant laterally encapsulates the second conductive terminals. In some embodiments, the first conductive terminals comprise first conductive bumps contacting the top surface of the interposer substrate, second conductive bumps in contact with the bottom surface of the first semiconductor die, and solder regions between the first conductive bumps and the second conductive bumps, and the second conductive terminals comprise first conductive pillars contacting the top surface of the interposer substrate, second conductive pads contacting the bottom surface of the second conductive die, and solder regions between the first conductive pillars and the second conductive pads. In some embodiments, the first conductive terminals are higher than the first conductive pillars, and a top surface of the first conductive bumps is substantially levels with a top surface of the first conductive pillars. In some embodiments, a top surface of the first portion of the insulating encapsulant substantially levels with a top surface of the first semiconductor die.

In accordance with some embodiments of the disclosure, a structure including an interposer substrate, a first semiconductor die, a second semiconductor die and an insulating encapsulant is provided. The first and second semiconductor dies are disposed on the interposer substrate. The first semiconductor die comprises first conductive terminals, and the second semiconductor die comprises second conductive terminals. The insulating encapsulant is disposed on the interposer substrate, wherein the insulating encapsulant laterally encapsulates the first semiconductor die, the second semiconductor die and the second conductive terminals. In some embodiments, the structure further comprises an underfill disposed between the first semiconductor die and the interposer substrate, wherein the insulating encapsulant is spaced part from the first conductive terminals by the underfill. In some embodiments, the insulating encapsulant is in contact with the second conductive terminals and the underfill. In some embodiments, the first conductive terminals are spaced laterally apart from each other by the underfill, and the second conductive terminals are spaced laterally apart from each other by the insulating encapsulant. In some embodiments, the interposer substrate comprises a semiconductor substrate, a redistribution structure and conductive terminals. The redistribution structure is electrically connected to the semiconductor substrate, and the conductive terminals are electrically connected to the redistribution structure. In some embodiments, the conductive terminals and the semiconductor substrate are disposed on opposite sides of the redistribution structure.

In accordance with some other embodiments of the disclosure, a method of manufacturing a semiconductor package is provided. The method includes the following steps: providing an interposer substrate having a first region and a second region; bonding a first semiconductor die with the first region of the interposer substrate; forming an underfill between the first semiconductor die and the first region of the interposer substrate; depositing an insulating encapsulant over the interposer substrate; performing a removal process for removing a portion of the insulating encapsulant to form a remaining portion of the insulating encapsulant, wherein the remaining portion of the insulating encapsulant covers the second portion region of the interposer substrate; performing a patterning process on the remaining portion of the insulating encapsulant to reveal the top surfaces of the first conductive pillars of the interposer substrate; and bonding a second semiconductor die with the first conductive pillars of the second region of the interposer substrate. In some embodiments, the removal process comprises a trimming process, and the patterning process comprises a laser drilling process. In some embodiments, the insulating encapsulant is formed via a molding process. In some embodiments, the insulating encapsulant is formed via a molding process followed by a patterning process.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A structure, comprising:
an interposer substrate;
a first semiconductor die disposed on the interposer substrate;
a second semiconductor die disposed on the interposer substrate;
an underfill disposed between the first semiconductor die and the interposer substrate; and
an insulating encapsulant disposed on the interposer substrate, wherein the insulating encapsulant comprises a first portion and a second portion, the first portion covers the second portion, the first portion laterally encapsulates the first semiconductor die and the second semiconductor die, and the second portion is disposed between the second semiconductor die and the interposer substrate.

2. The structure of claim 1, wherein the first semiconductor die is electrically connected to the interposer substrate via first conductive terminals between a top surface of the interposer substrate and a bottom surface of the first semiconductor die.

3. The structure of claim 1, wherein the second semiconductor die is electrically connected to the interposer substrate via second conductive terminals between the top surface of the interposer substrate and a bottom surface of the second semiconductor die.

4. The structure of claim 2, wherein the first conductive terminals comprise first conductive bumps contacting the top surface of the interposer substrate, second conductive bumps in contact with the bottom surface of the first semiconductor die, and solder regions between the first conductive bumps and the second conductive bumps.

5. The structure of claim 3, wherein the second conductive terminals comprise first conductive pillars contacting the top surface of the interposer substrate, second conductive pads contacting the bottom surface of the second conductive die, and solder regions between the first conductive pillars and the second conductive pads.

6. The structure of claim 5, wherein the first conductive terminals are higher than first conductive pillars, and a top surface of the first conductive bumps substantially levels with a top surface of the first conductive pillars.

7. The structure of claim 1, wherein a top surface of the first portion substantially levels with a top surface of the first semiconductor die.

8. A structure, comprising:
an interposer substrate;
a first semiconductor die disposed on the interposer substrate, the first semiconductor die comprising first conductive terminals;
a second semiconductor die disposed on the interposer substrate, the second semiconductor die comprising second conductive terminals; and
an insulating encapsulant disposed on the interposer substrate, wherein the insulating encapsulant laterally encapsulates the first semiconductor die, the second semiconductor die and the second conductive terminals.

9. The structure of claim 8 further comprising an underfill disposed between the first semiconductor die and the interposer substrate, wherein the insulating encapsulant is spaced part from the first conductive terminals by the underfill.

10. The structure of claim 9, wherein the insulating encapsulant is in contact with the second conductive terminals and the underfill.

11. The structure of claim 9, wherein the first conductive terminals are spaced laterally apart from each other by the underfill, and the second conductive terminals are spaced laterally apart from each other by the insulating encapsulant.

12. The structure of claim 8, wherein the interposer substrate comprises a semiconductor substrate, a redistribution structure and conductive terminals, the redistribution structure is electrically connected to the semiconductor substrate, the conductive terminals are electrically connected to the redistribution structure, and wherein the conductive terminals and the semiconductor substrate are disposed on opposite sides of the redistribution structure.

13. A method, comprising:
providing an interposer substrate having a first region and a second region;
bonding a first semiconductor die with the first region of the interposer substrate;
depositing an insulating encapsulant over the interposer substrate, wherein the insulating encapsulant laterally encapsulates the first semiconductor die, and first conductive pillars of the second region of the interposer substrate, revealing top surfaces of the first conductive pillars; and
bonding a second semiconductor die with the first conductive pillars of the second region of the interposer substrate.

14. The method of claim 13, further comprising:
forming an underfill between the first semiconductor die and the first region of the interposer substrate, wherein a sidewall of the underfill is in contact with the insulating encapsulant.

15. The method of claim 13, further comprising:
forming an underfill between the first semiconductor die and the first region of the interposer substrate, wherein the underfill laterally encapsulates first conductive terminals of the first semiconductor die.

16. The method of claim 13, further comprising:
performing a removal process for removing a portion of the insulating encapsulant to form a remaining portion of the insulating encapsulant, wherein the remaining portion of the insulating encapsulant covers the second region of the interposer substrate; and
performing a patterning process on the remaining portion of the insulating encapsulant to reveal the top surfaces of the first conductive pillars of the interposer substrate.

17. The method of claim 16, wherein the removal process comprises a trimming process, and the patterning process comprises a laser drilling process.

18. The method of claim 13, further comprising:
performing a patterning process on the insulating encapsulant to reveal the top surfaces of the first conductive pillars of the interposer substrate.

19. The method of claim 13, wherein the insulating encapsulant is formed via a molding process.

20. The method of claim 13, wherein the insulating encapsulant is formed via a molding process followed by a patterning process.
